(19) United States
(12) Patent Application Publication
(10) Pub. No.: US 2025/0040372 A1
(43) Pub. Date: Jan. 30, 2025

(54) DISPLAY PANEL AND METHOD FOR MANUFACTURING THE SAME

(71) Applicant: Samsung Display Co., LTD., Yongin-si (KR)

(72) Inventors: TAEOH KIM, Yongin-si (KR); BYUNGHOON KIM, Yongin-si (KR); JEONGJIN PARK, Yongin-si (KR)

(21) Appl. No.: 18/760,710

(22) Filed: Jul. 1, 2024

(30) Foreign Application Priority Data
Jul. 28, 2023 (KR) 10-2023-0098969

(51) Int. Cl. H10K 59/131; H10K 59/12

(52) U.S. Cl. CPC H10K 59/131; H10K 59/1201

(57) ABSTRACT

A method for manufacturing a display panel includes: preparing for a base layer including a pad inside the base layer, forming an opening such that the pad are exposed by etching a portion of the base layer, preparing for a circuit film having a preliminary circuit film line provided in the circuit film, forming a circuit film line from the preliminary circuit film line by irradiating a laser beam to the circuit film, disposing the base layer and the circuit film such that the pad and the circuit film line overlap each other on a stage, and disposing a transfer substrate on the base layer, and forming a conductive pattern on the pad and the circuit film line, where the forming of the conductive pattern includes irradiating a first laser beam on the transfer substrate.

This application claims priority to Korean Patent Application No. 10-2023-0098969, filed on Jul. 28, 2023, and all the benefits accruing therefrom under 35 U.S.C. § 119, the content of which in its entirety is herein incorporated by reference.

### BACKGROUND

Embodiments of the present disclosure described herein relate to a display panel and a method for manufacturing the same.

A display device, such as televisions, monitors, smart phones, and tablets include a display panel. The display panel includes a display variously developed, for example, a liquid crystal display panel, an organic light emitting display panel, an electro-wetting display panel, and an electrophoretic display panel.

Studies and researches have been conducted to reduce a region, in which an image is not displayed, from a display, to meet market demand. In addition, studies and researches have been conducted to enlarge a display region for displaying an image in a display panel.

### SUMMARY

Embodiments of the present disclosure provide a display panel having an area reduced in a non-display region and a method for manufacturing the same.

According to an embodiment of the present disclosure, a method for manufacturing a display panel includes: preparing for a base layer including a plurality of pads inside the base layer, forming an opening such that the plurality of pads are exposed by etching a portion of the base layer, preparing for a circuit film having a preliminary circuit film line provided in the circuit film; forming a circuit film line from the preliminary circuit film line by irradiating a laser beam to the circuit film, disposing the base layer and the circuit film such that the plurality of pads and the circuit film line overlap each other on a stage, and disposing the transfer substrate on the base layer and forming a conductive pattern on the plurality of pads and the circuit film line, where the forming of the conductive pattern includes irradiating a first laser beam on the transfer substrate.

The forming of the circuit film line may include etching a portion of the circuit film to expose a portion of the preliminary circuit film line.

The transfer substrate may include a donor film and a transparent substrate disposed on the donor film.

The forming of the conductive pattern may include irradiating, by a laser generator, the first laser beam in a first direction, changing a direction of the first laser beam from the first direction toward the transparent substrate through a lens disposed on the transfer substrate, and transferring a portion of the donor film through the first laser beam irradiated toward the transparent substrate.

The forming of the conductive pattern may further include moving the laser generator and the lens in the first direction or a second direction crossing the first direction.

The forming of the conductive pattern may further include moving the stage in the first direction or a second direction crossing the first direction.

The forming of the conductive pattern may include irradiating the first laser beam in the first direction by the laser generator, changing the direction of the first laser beam to a direction from the first direction toward the transparent substrate by a scanner disposed on the transfer substrate, and transferring a portion of the donor film by consecutively changing the direction of the first layer beam by the scanner.

The forming of the conductive pattern may include disposing a mask on the transfer substrate, irradiating the first laser beam along the mask by a laser generator, and transferring a portion of the donor film by the first laser beam transmitted through the mask. The first laser beam may be a line laser beam.

A method for manufacturing the display panel may further include irradiating a second laser beam to a region in which a film line overlaps the conductive pattern, and the second laser beam may weld the circuit film line to the conductive pattern through a conductive pattern.

The second laser beam may be an infrared laser beam.

The base layer may include a first region and a second region, a plurality of pixels may be disposed on the first region, and the opening may overlap the first region of the base layer.

The disposing of the base layer and the circuit film and disposing a transfer substrate on the base layer may include disposing the base layer and the circuit film such that the plurality of pads overlap the circuit film in the opening of the base layer.

The disposing of the base layer and the circuit film and disposing a transfer substrate on the base layer may include disposing the base layer and the circuit film such that the plurality of pads, the circuit film, and a portion of the circuit film overlap each other in the opening of the base layer.

According to an embodiment of the present disclosure, a display panel includes: a base layer in which a first region and a second region are defined, a plurality of pixels disposed on the first region of the base layer, a plurality of pads interposed between a top surface and a bottom surface of the base layer, a circuit film disposed on the plurality of pads and the bottom surface of the base layer, a circuit film line disposed on the plurality of pads, and having a portion extending from the circuit film, and a conductive pattern disposed on the circuit film line and the plurality of pads. An opening is defined on the base layer in a thickness direction of the base layer, and the plurality of pads, the circuit film line, and the conductive pattern may be disposed in the opening.

A portion of the circuit film may be disposed inside the opening.

The base layer may include a first sub-base layer including the bottom surface of the base layer and having the opening defined in the first sub-base layer, barrier layers disposed on the first sub-base layer, and a second sub-base layer disposed on the barrier layers and including the top surface of the base layer. The plurality of pads may be disposed in the barrier layers, and are exposed by the opening of the first sub-base layer.

In a plan view, the width of the circuit film line may be equal to or less than the width of each of the plurality of pads.

In a plan view, the width of the conductive pattern may be equal to or less than the width of the circuit film line.

The opening may overlap the first region.

The opening may overlap the first region and the second region.

The conductive pattern may weld the circuit film line to the plurality of pads.

The conductive pattern may be the form of a thin film.

### BRIEF DESCRIPTION OF THE FIGURES

The above and other aspects and features of the present disclosure will become apparent by describing in detail embodiments thereof with reference to the accompanying drawings.

FIG. 1 is a perspective view of a display device according to an embodiment of the present disclosure.

FIG. 2 is a schematic cross-sectional view of a display device according to an embodiment of the present disclosure.

FIG. 3 is a cross-sectional view of a display panel according to an embodiment of the present disclosure.

FIG. 4 is a bottom-up plan view of a display panel according to an embodiment of the present disclosure.

FIG. 5A is an enlarged view of an attachable region according to an embodiment of the present disclosure.

FIG. 5B is a perspective view of an attachable region according to an embodiment of the present disclosure.

FIG. 6 is a cross-sectional view taken along line I-I′ of FIG. 5A.

FIG. 7 is a bottom-up plan view of a display panel according to another embodiment of the present disclosure.

FIGS. 8 to 13 are perspective views illustrating a portion of a method for manufacturing a display panel according to an embodiment of the present disclosure.

### DETAILED DESCRIPTION

In the specification, the expression that a first component (or region, layer, part, portion, etc.) is “on”, “connected to”, or “coupled to” a second component means that the first component is directly on, connected to, or coupled to the second component or means that a third component is interposed therebetween.

The same reference numeral will be assigned to the same component. In addition, in drawings, thicknesses, proportions, and dimensions of components may be exaggerated to describe the technical features effectively. The term “and/or” includes any and all combinations of one or more of associated components

Although the terms “first”, “second”, etc. may be used to describe various components, the components should not be construed as being limited by the terms. The terms are only used to distinguish one component from another component. For example, without departing from the scope and spirit of the invention, a first component may be referred to as a second component, and similarly, the second component may be referred to as the first component. The singular forms are intended to include the plural forms unless the context clearly indicates otherwise.

In addition, the terms “under”, “at a lower portion”, “above”, “an upper portion” are used to describe the relationship between components illustrated in drawings. The terms are relative and are described with reference to a direction indicated in the drawing.

It will be further understood that the terms “comprises,” “comprising,” “includes,” or “including,” or “having” specify the presence of stated features, numbers, steps, operations, components, parts, or the combination thereof, but do not preclude the presence or addition of one or more other features, numbers, steps, operations, components, components, and/or the combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

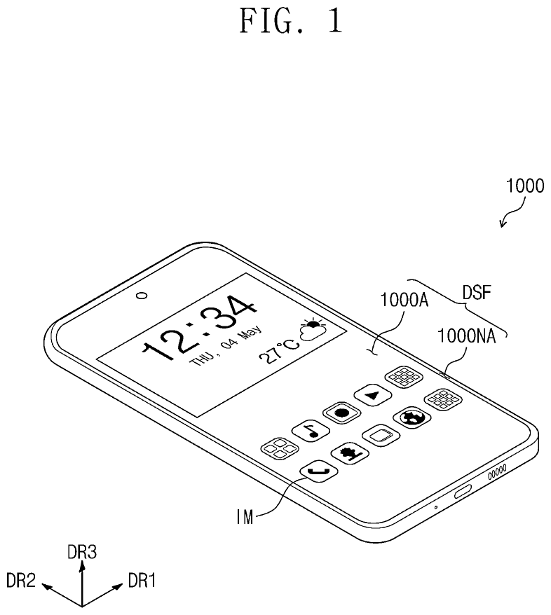

FIG. 1 is a perspective view of a display device 1000 according to an embodiment of the present disclosure.

Referring to FIG. 1, the display device 1000 may refer to a device which is activated in response to an electrical signal. For example, the display device 1000 may be a cellular phone, a tablet PC, a car navigation system, a game console, or a wearable device, but is not limited thereto. FIG. 1 illustrates that the display device 1000 is the cellular phone.

The display device 1000 may include a display surface DSF defined by a first direction DR1 and a second direction DR2 crossing the first direction DR1. The display device 1000 may provide an image IM to the user through the display surface DSF. The display surface DSF may include a display region 1000A and a non-display region 1000NA around the display region 1000A. The display region 1000A may display the image IM, and the non-display region 1000NA may not display the image IM. The non-display region 1000NA may surround the display region 1000A. However, the present disclosure is not limited thereto, and the form of the display region 1000A and the form of the non-display region 1000NA may be deformed in another embodiment.

According to the present disclosure, the area of the non-display region 1000NA may be reduced. Accordingly, the ratio of an area occupied by the display region 1000A in the whole area of the display surface DSF may be increased. Accordingly, the display device 1000 reduced in bezel width may be provided. The details thereof will be described later.

Hereinafter, a direction substantially perpendicular to a plane defined by the first direction DR1 and the second direction DR2 is defined as a third direction DR3. The third direction DR3 may serve as a basis for distinguishing between a front surface and a rear surface of members. In the present disclosure, the wording “in a plan view” may refer to the state when viewed in the third direction DR3. Hereinafter, the first to third directions DR1, DR2, and DR3 are directions indicated by the first to third direction axes, respectively, and the directions indicated by the first to third direction axes may be assigned with the same reference numerals.

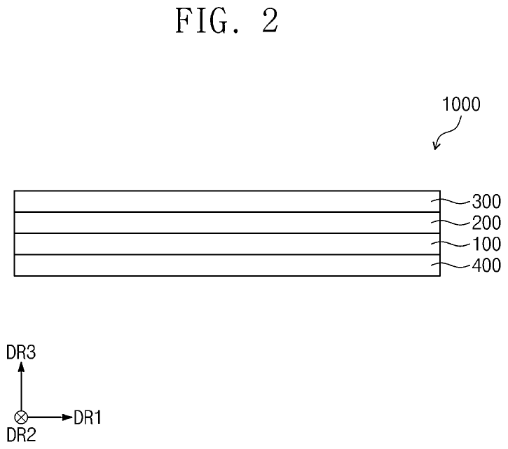

FIG. 2 is a cross-sectional view schematically illustrating the display device 1000 according to an embodiment of the present disclosure.

Referring to FIG. 2, the display device 1000 may include a display panel 100, an optical film 200, a window 300, and a lower film 400. The display device 1000 may include a structure in which the window 300, the optical film 200, the display panel 100, and the lower film 400 are sequentially stacked. According to an embodiment of the present disclosure, some of the above components may be omitted, and another component may be additionally added. An adhesive layer may be disposed between the members. The adhesive layer may be an optically clear adhesive (“OCA”) or a pressure sensitive adhesive film (“PSA”), but the present disclosure is not limited thereto. The adhesive layers described below may also include the same material and a typical adhesive in another embodiment.

The display panel 100 may display an image and may sense an external input applied from the outside. The external input may include various inputs applied from an outside of the display device 1000. For example, as well as a contact by a part, such as a user hand, of a body, the external input may include an external input (for example, a hovering) which is applied in a state where the user hand approaches the display device 1000 or is adjacent to the display device 1000 within a given distance. Also, the external input may have various types such as force, a pressure, a temperature, and a light. The external input may be provided by a separate device, for example, an active pen or a digitizer pen.

The optical film 200 may reduce reflectance of light incident on the optical film 200 from the outside. The optical film 200 may include a phase retarder and/or a polarizer. The optical film 200 may include at least a polarizing film. In this case, the optical film 200 may be attached to the display panel 100 through an adhesive layer.

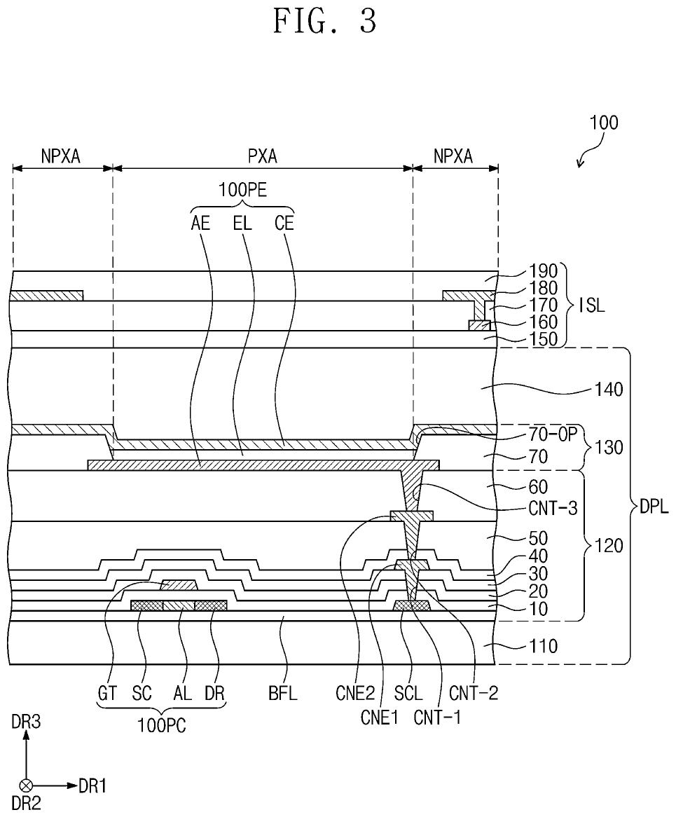

Alternatively, the optical film 200 may include color filters. The color filters may have a specific arrangement. The arrangement of the color filters may be determined based on colors of light emitting from pixels included in a display layer DPL (see FIG. 3). Also, the optical film 200 may further include a black matrix adjacent to the color filters. In this case, the adhesive layer may be omitted between the optical film 200 and the display panel 100.

Alternatively, the optical film 200 may include a destructive interference structure. In an embodiment, for example, the destructive interference structure may include a first reflective layer and a second reflective layer which are disposed at mutually different layers. First reflective light and second reflective light emitted from the first reflective layer and the second reflective layer, respectively, may destructive-interfere with each other. In this case, the adhesive layer may be omitted between the optical film 200 and the display panel 100.

The window 300 may be disposed on the optical film 200. The window 300 may include an optically transparent material. In an embodiment, for example, the window 300 may include glass or plastic. The window 300 may have a multi-layer structure or a single-layer structure. In an embodiment, for example, the window 300 may include a plurality of plastic films bonded to each other by an adhesive or may have a glass substrate and a plastic film bonded to each other by the adhesive.

The lower film 400 may be disposed under the display panel 100. In an embodiment, for example, the lower film 400 may be a protective layer which blocks or absorbs light incident on the display panel 100. In an embodiment, for example, the lower film 400 may be a colored film. However, the present disclosure is not specifically limited thereto.

FIG. 3 is a cross-sectional view of the display panel 100 according to an embodiment of the present disclosure.

Referring to FIG. 3, the display panel 100 may include the display layer DPL and a sensor layer ISL disposed on the display layer DPL. The display layer DPL may be configured to actually generate an image. The display layer DPL may be a light emitting display layer. In an embodiment, for example, the display layer DPL may be an organic light emitting display layer, a quantum dot display layer, a micro-LED display layer, or a nano-LED display layer. The sensor layer ISL may be disposed on the display layer DPL. The sensor layer ISL may sense an external input applied from the outside. The sensor layer ISL may be an external sensor attached to the display layer DPL, or may be an integral-type sensor formed subsequently during the manufacturing process of the display layer DPL.

The display layer DPL may include a base layer 110, a circuit layer 120, a light emitting element layer 130, and an encapsulating layer 140.

The base layer 110 may be a member which provides a base surface for disposing the circuit layer 120. The base layer 110 may have a synthetic resin layer. The synthetic resin layer may be a polyimide-based resin layer, and the material of the synthetic resin layer is not specifically limited. Besides, the base layer 110 may include a glass substrate, a metal substrate, an organic/inorganic composite material substrate.

At least one inorganic layer may be disposed on a top surface of the base layer 110. The inorganic layer may include at least one of an aluminum oxide, a titanium oxide, a silicon oxide, a silicon nitride, a silicon oxynitride, a zirconium oxide, or a hafnium oxide. The inorganic layer may be formed at multiple layers. Multiple inorganic layers may constitute a barrier layer and/or a buffer layer. According to an embodiment, the display layer DPL is illustrated as including a buffer layer BFL.

The buffer layer BFL may improve bonding force between the base layer 110 and a semiconductor pattern. The buffer layer BFL may include at least one of silicon oxide, silicon nitride, or silicon oxynitride. In an embodiment, for example, the buffer layer BFL may include a structure in which a silicon oxide layer and a silicon nitride layer are alternately stacked.

The semiconductor pattern may be disposed on the buffer layer BFL. The semiconductor pattern may include polysilicon. However, the present disclosure is not limited thereto. For another example, the semiconductor pattern may include amorphous silicon, low-temperature polycrystalline silicon, or oxide semiconductor.

Some semiconductor patterns are merely illustrated in FIG. 3, and other semiconductor patterns may be further disposed in another region. The semiconductor patterns may be arranged in a specific rule, while crossing the pixels. The semiconductor pattern may have a different electrical property depending on whether doped. The semiconductor patterns may include a first region having higher conductivity and a second region having lower conductivity. The first region may be doped with N-type dopants or P-type dopants. A P-type transistor may include a doping region doped with the P-type dopant, and an N-type transistor may include a doping region doped with the N-type dopant. The second region may be a non-doping region or may be a region doped at a concentration lighter than the concentration of the first region.

The conductivity of the first region may be higher than the conductivity of the second region. The first region may actually serve as an electrode or a signal line. The second region may actually correspond to an active region (or channel) of a transistor. In other words, a portion of the semiconductor pattern may be an active region of a transistor, another portion of the semiconductor pattern may be a source region or a drain region of the transistor, and still another portion of the semiconductor pattern may be a connection electrode or a connection signal line

Each of pixels may have an equivalent circuit including seven transistors, one capacitor, and a light emitting element, and the equivalent circuit of the pixel may be modified in various forms. FIG. 3 illustrates that the pixel includes one transistor 100PC and one light emitting element 100PE, by way of example.

A source SC, an active region AL, and a drain DR of the transistor 100PC may be formed from the semiconductor pattern. The source SC and the drain DR may extend from the active region AL in directions opposite to each other in the cross-sectional view. A portion of a connection signal line SCL formed from the semiconductor pattern is illustrated in FIG. 3. Although not separately illustrated, the connection signal line SCL may be connected with the drain region DR of the transistor 100PC in a plan view.

A first insulating layer 10 may be disposed on the buffer layer BFL. The first insulating layer 10 may be commonly provided in a plurality of pixels to cover the semiconductor pattern. The first insulating layer 10 may be an inorganic layer and/or an organic layer, and may have a single-layer structure or a multi-layer structure. The first insulating layer 10 may include at least one of an aluminum oxide, a titanium oxide, a silicon oxide, a silicon nitride, a silicon oxynitride, a zirconium oxide, or a hafnium oxide. According to the present embodiment, the first insulating layer 10 may be a silicon oxide layer having a single-layer structure. The first insulating layer 10 and an insulating layer of the circuit layer 120, which is to be described later, may be an inorganic layer and/or an organic layer, and may have a single-layer structure or a multi-layer structure. The inorganic layer may include, but is not limited to, at least one of the above-described materials.

A gate GT of the transistor 100PC is disposed on the first insulating layer 10. The gate GT may be a portion of a metal pattern. The gate GT overlaps the active region AL in a plan view. The gate GT may function as a mask in a process of doping the semiconductor pattern.

A second insulating layer 20 may be disposed on the first insulating layer 10 to cover the gate GT. The second insulating layer 20 may commonly overlap the pixels in a plan view. The second insulating layer 20 may be an inorganic layer and/or an organic layer, and may have a single-layer or multilayer structure. The second insulating layer 20 may include at least one of silicon oxide, silicon nitride, or silicon oxynitride. According to the present embodiment, the second insulating layer 20 may have a multi-layer structure including a silicon oxide layer and a silicon nitride layer.

A third insulating layer 30 may be disposed on the second insulating layer 20. The third insulating layer 30 may have a single-layer or multilayer structure. According to the present embodiment, the third insulating layer 30 may have a multi-layer structure including a silicon oxide layer and a silicon nitride layer.

A first connection electrode CNE1 may be disposed on the third insulating layer 30. The first connection electrode CNE1 may be connected to the connection signal line SCL through a contact hole CNT-1 formed through the first insulating layer 10, the second insulating layer 20, and the third insulating layer 30.

A fourth insulating layer 40 may be disposed on the third insulating layer 30. The fourth insulating layer 40 may be a single silicon oxide layer. A fifth insulating layer 50 may be disposed on the fourth insulating layer 40. The fifth insulating layer 50 may be an organic layer.

A second connection electrode CNE2 may be disposed on the fifth insulating layer 50. The second connection electrode CNE2 may be connected to the first connection electrode CNE1 through a contact hole CNT-2 formed through the fourth insulating layer 40, and the fifth insulating layer 50.

A sixth insulating layer 60 may be disposed on the fifth insulating layer 50 and may cover the second connection electrode CNE2. The sixth insulating layer 60 may be an organic layer.

The light emitting element layer 130 may be disposed on the circuit layer 120. The light emitting element layer 130 may include the light emitting element 100PE. In an embodiment, for example, the light emitting element layer 130 may include an organic light emitting material, an inorganic light emitting material, an organic-inorganic light emitting material, a quantum dot, a quantum rod, a micro-LED, or a nano-LED. The following description will be described regarding the light emitting element 100PE which is an organic light emitting element, by way of example, but the present disclosure is not specifically limited thereto.

The light emitting element 100PE may include a first electrode AE, a light emitting layer EL, and a second electrode CE.

The first electrode AE may be disposed on the sixth insulating layer 60. The first electrode AE may be connected with the second connection electrode CNE2 through a contact hole CNT-3 formed through the sixth insulating layer 60.

A pixel defining layer 70 may be disposed on the sixth insulating layer 60 and may cover a portion of the first electrode AE. An opening 70-OP is defined in the pixel defining layer 70. The opening 70-OP of the pixel defining layer 70 exposes at least a portion of the first electrode AE.

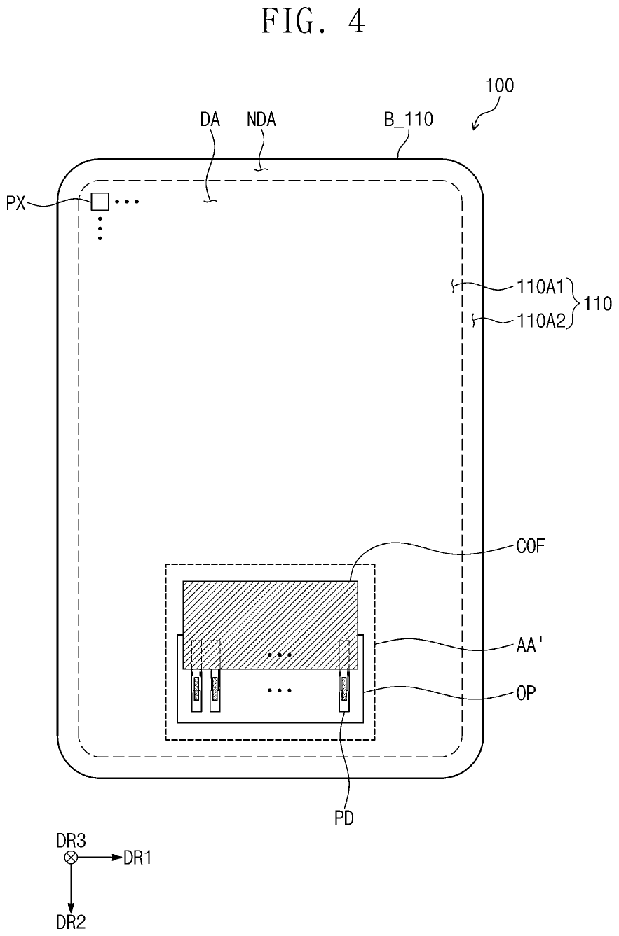

A display region DA (see FIG. 4) may include a light emitting region PXA and a non-light emitting region NPXA adjacent to the light emitting region PXA. The non-light emitting region NPXA may surround the light emitting region PXA. According to an embodiment, the light emitting region PXA is defined to correspond to the portion of the first electrode AE, which is exposed by the opening 70-OP.

The light emitting layer EL may be disposed on the first electrode AE. The light emitting layer EL may be disposed in a region defined by the opening 70-OP. In other words, the light emitting layer EL may be separately disposed in each of pixels. When the light emitting layer EL is separately disposed in each pixel, each of the light emitting layers EL may emit light of at least one of a blue color, a red color, or a green color. However, the present disclosure is not limited thereto, and the light emitting layer EL may be connected with the pixels and commonly provided in the pixels in another embodiment. In this case, the light emitting layer EL may provide blue light or white light.

The second electrode CE may be disposed on the light emitting layer EL. The second electrode CE may have an integral-type form, and may be commonly disposed in the plurality of pixels.

Although not illustrated, a hole control layer may be interposed between the first electrode AE and the light emitting layer EL. The hole control layer may be commonly disposed in the light emitting region PXA and the non-light emitting region NPXA. The hole control layer may include a hole transport layer and may further include a hole injection layer. An electron control layer may be interposed between the light emitting layer EL and the second electrode CE. The electron control layer may include an electron transport layer, and may further include an electron injection layer. The hole control layer and the electron control layer may be commonly formed in the pixels by using an open mask.

The encapsulating layer 140 may be disposed on the light emitting element layer 130. The encapsulating layer 140 may include an inorganic layer, an organic layer, and an inorganic layer sequentially stacked, and layers constituting the encapsulating layer 140 are not limited thereto.’

The inorganic layers may protect the light emitting element layer 130 from moisture and oxygen, and the organic layer may protect the light emitting element layer 130 from a foreign material such as dust particles. The inorganic layers may include a silicon nitride layer, a silicon oxynitride layer, a silicon oxide layer, a titanium oxide layer, an aluminum oxide layer, or the like. The organic layer may include, but is not limited to, an acrylic-based organic layer.

The sensor layer ISL may include a base layer 150, a first conductive layer 160, a sensing insulating layer 170, a second conductive layer 180, and a cover insulating layer 190.

The base layer 150 may be an inorganic layer including at least one of silicon nitride, silicon oxynitride, or silicon oxide. Alternatively, the base layer 150 may be an organic layer including epoxy resin, acrylate resin, or imide-based resin. The base layer 150 may have a single-layer structure or may have a multi-layer structure stacked in the third direction DR3. According to an embodiment, the base layer 150 may be omitted.

Each of the first conductive layer 160 and the second conductive layer 180 may have a single-layer structure or a multi-layer structure stacked in the third direction DR3.

The conductive layer in a single-layer structure may include a metal layer or a transparent conductive layer. The metal layer may include molybdenum, silver, titanium, copper, aluminum, or the alloy thereof. The transparent conductive layer may include transparent conductive oxide such as indium tin oxide (“ITO”), indium zinc oxide (“IZO”), zinc oxide (ZnO), or indium zinc tin oxide (“IZTO”). In addition, the transparent conductive layer may include conductive polymer, such as PEDOT, a metal nano-line, or graphene.

The conductive layer in the multi-layer structure may include metal layers. The metal layers may have, for example, a three-layer structure of titanium/aluminum/titanium. The conductive layer in the multi-layer structure may include at least one metal layer and at least one transparent conductive layer.

At least one of the sensing insulating layer 170 or the cover insulating layer 190 may include an inorganic film. The inorganic film may include at least one of an aluminum oxide, a titanium oxide, a silicon oxide, a silicon nitride, a silicon oxynitride, a zirconium oxide, or hafnium oxide.

At least one of the sensing insulating layer 170 or the cover insulating layer 190 may include an organic film. The organic film may include at least one of acrylic resin, methacrylic resin, polyisoprene, vinyl resin, epoxy resin, urethane resin, cellulose resin, siloxane resin, polyimide resin, polyamide resin, or perylene resin.

FIG. 4 is a plan view of the display panel 100 according to an embodiment of the present disclosure. FIG. 4 is a bottom-up plan view illustrating a bottom surface B_110 of the display panel 100.

Referring to FIG. 4, the display panel 100 may include the display region DA and a non-display region NDA. A first region 110A1 of the base layer 110 may overlap the display region DA, and a second region 110A2 of the base layer 110 may overlap the non-display region NDA in a plan view. In other words, the first region 110A1 of the base layer 110 may be a base surface for providing components disposed in the display region DA, and the second region 110A2 of the base layer 110 may be a base surface for providing components disposed in the non-display region NDA.

The plurality of pixels PX may be disposed in the display region DA. In an embodiment, for example, the plurality of pixels PX may be disposed in the first region 110A1. A plurality of lines may be disposed on the base layer 110, and may be electrically connected to the pixels PX.

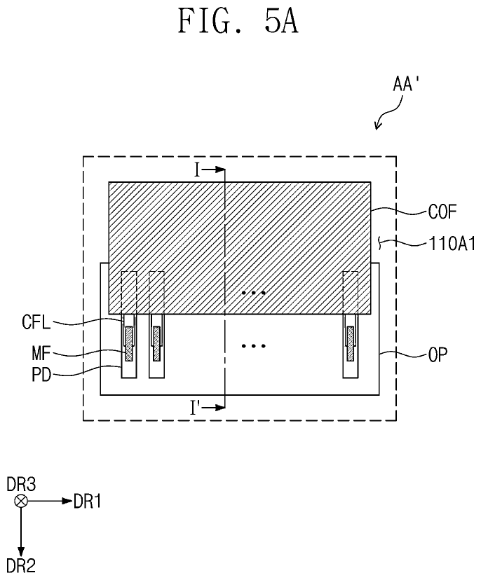

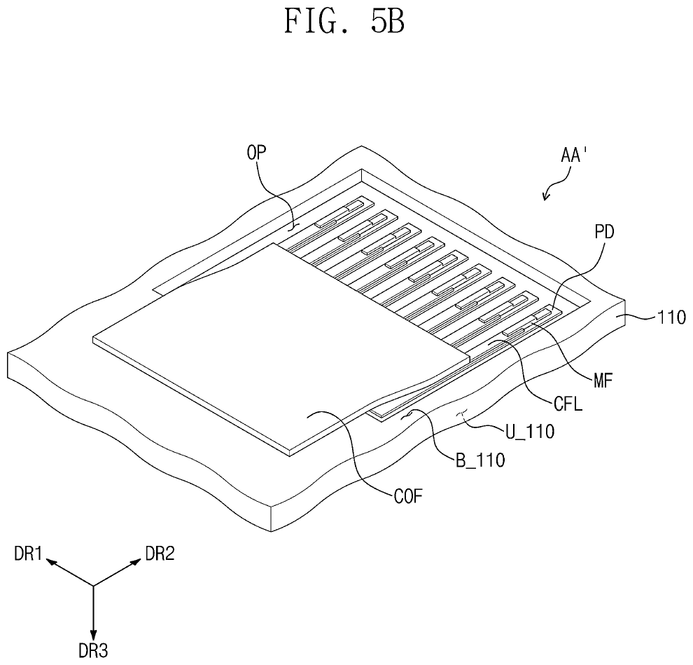

A plurality of pads PD may be interposed between a top surface U_110 (see FIG. 5B) and the bottom surface B_110 of the base layer 110. An attachable region AA′ for attaching a circuit film COF thereto may be defined in the display panel 100. The circuit film COF may be placed under the display panel 100, and the circuit film COF may be attached to the plurality of pads PD exposed through an opening OP defined in the base layer 110.

The attachable region AA′ may overlap the display region DA in a plan view. In other words, the opening OP of the base layer 110 may overlap the first region 110A1 of the base layer 110 in a plan view. However, the position of the opening OP in the base layer 110 is provided for the illustrative purpose, and the present disclosure is not limited thereto.

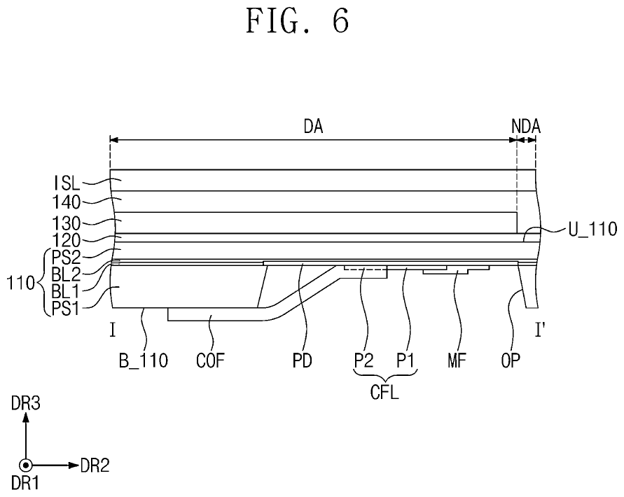

FIG. 5A is an enlarged view of the attachable region AA′ according to an embodiment of the present disclosure. FIG. 5B is a rear perspective view of the attachable region AA′ according to an embodiment of the present disclosure. FIG. 6 is a cross-sectional view taken along line I-I′ of FIG. 5A.

Referring to FIGS. 4 to 6, the base layer 110 may include the top surface U_110 and the bottom surface B_110. The top surface U_110 of the base layer 110 may be a surface in contact with the circuit layer 120 (see FIG. 3). The bottom surface B_110 of the base layer 110 may be a surface facing the top surface U_110 of the base layer 110 and a bottom surface of the display panel 100 (see FIG. 3). The opening OP may be defined in the base layer 110 in a thickness direction (e.g., the third direction DR3) of the base layer 110. The base layer 110 may include a polyimide (“PI”).

The base layer 110 may include a first sub-base layer PS1, barrier layers BL1 and BL2, and a second sub-base layer PS2. The first sub-base layer PS1 may include the bottom surface B_110 of the base layer 110, and the opening OP may be defined in the first sub-base layer PS1. The barrier layers BL1 and BL2 may be disposed on the first sub-base layer PS1. The barrier layers BL1 and BL2 may include the first barrier layer BL1 and the second barrier layer BL2. The first barrier layer BL1 may be disposed on the first sub-base layer PS1, and the second barrier layer BL2 may be disposed on the first barrier layer BL1. The second sub-base layer PS2 may be disposed on the barrier layers BL1 and BL2, and may include the top surface U_110 of the base layer 110.

The display panel 100 may include the plurality of pads PD, the circuit film COF, a circuit film line CFL, and a conductive pattern MF. The plurality of pads PD, a portion of the circuit film COF, the circuit film line CFL, and the conductive pattern MF may be disposed in the opening OP.

The plurality of pads PD may be interposed between the top surface U_110 and the bottom surface B_110 of the base layer 110. The plurality of pads PD may be disposed in the barrier layers BL1 and BL2. The plurality of pads PD may be exposed by the opening OP of the first sub-base layer PS1.

The circuit film COF may be disposed under the display panel 100. In detail, the circuit film COF may be disposed on the plurality of pads PD and the bottom surface B_110 of the base layer 110. The circuit film COF may include polyimide (PI).

The circuit film line CFL may be disposed on the plurality of pads PD. A portion P1 (first portion) of the circuit film line CFL may be exposed to the outside of the circuit film COF, and another portion P2 (second portion) of the circuit film line CFL may be included in the circuit film COF. In other words, the portion P1 of the circuit film line CFL may extend from the circuit film COF. The circuit film line CFL may include a metallic material. In an embodiment, for example, the circuit film line CFL may include copper (Cu) or silver (Ag). The plurality of circuit film lines CFL may be provided. In an embodiment, for example, the circuit film line CFL may be provided in one-to-one correspondence with the plurality of pads PD. A width of one circuit film line CFL in a plan view may be equal to or less than a width of each of the plurality of pads PD.

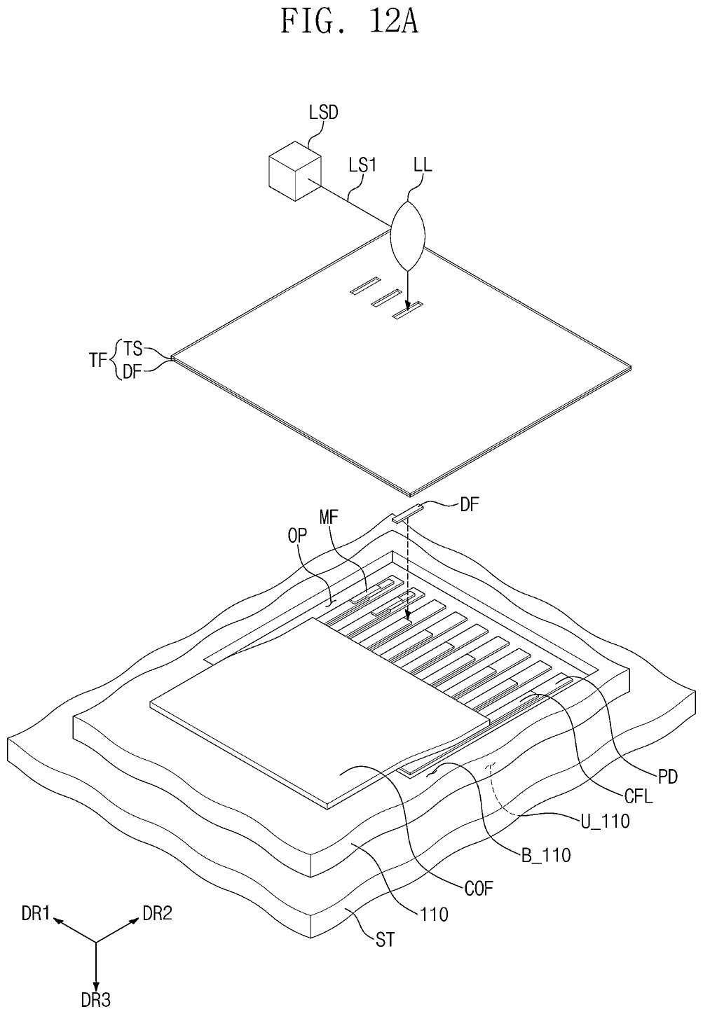

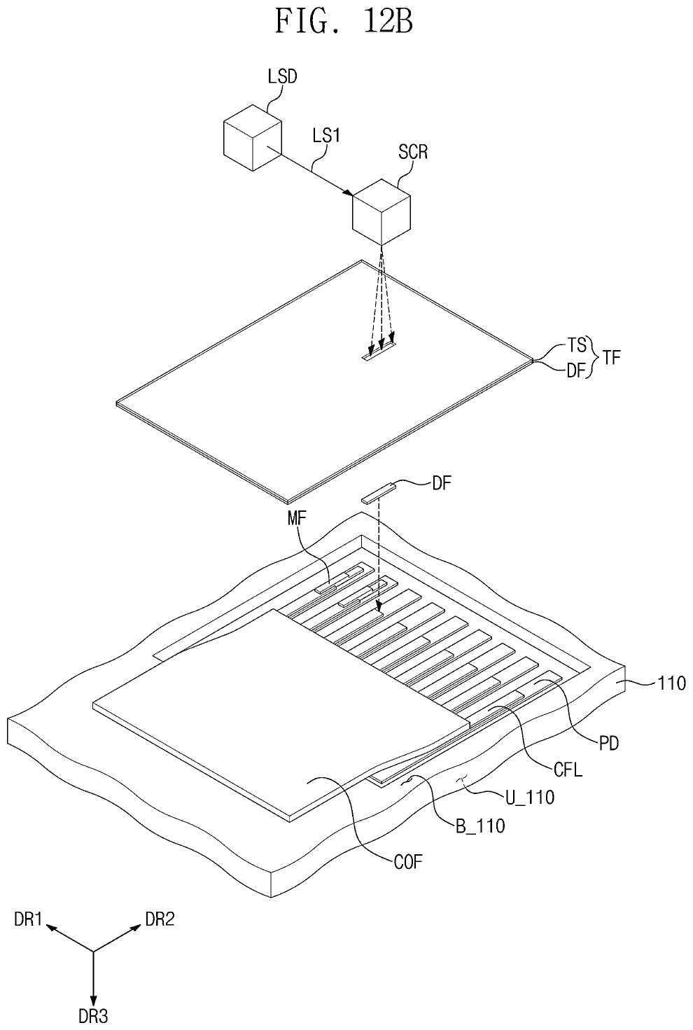

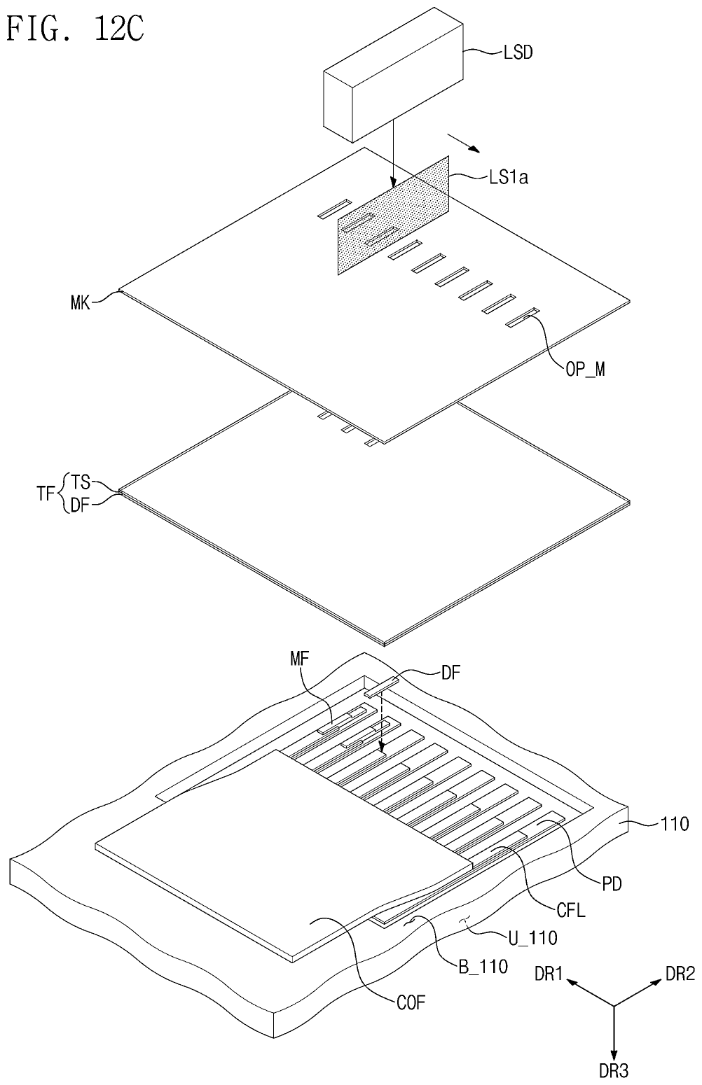

The conductive pattern MF may be disposed on the circuit film line CFL and the plurality of pads PD. The conductive pattern MF of the present disclosure may be formed by transferring a donor film DF (see FIG. 12A). When the donor film DF is transferred to form the conductive pattern MF, a distance between the conductive patterns MF may be decreased. In an embodiment, for example, the distance between the two conductive patterns MF may be 10 μm to 20 μm. The conductive pattern MF may be in the form of a thin film. In other words, the conductive pattern MF does not have a hemispherical shape, and the thickness of the conductive pattern MF may be constant. Since the conductive pattern MF is in the form of a thin film, the damage to the base layer 110 due to the laser process may be reduced or removed, as compared with when the conductive material is applied in a hemispherical shape.

The conductive pattern MF may connect the circuit film line CFL to the plurality of pads PD. The plurality of conductive patterns MF may be provided. In an embodiment, for example, the conductive pattern MF may be provided in one-to-one correspondence with the circuit film line CFL or the plurality of pads PD. In a plan view, a width of one conductive pattern MF may be equal to or less than a width of one circuit film line CFL.

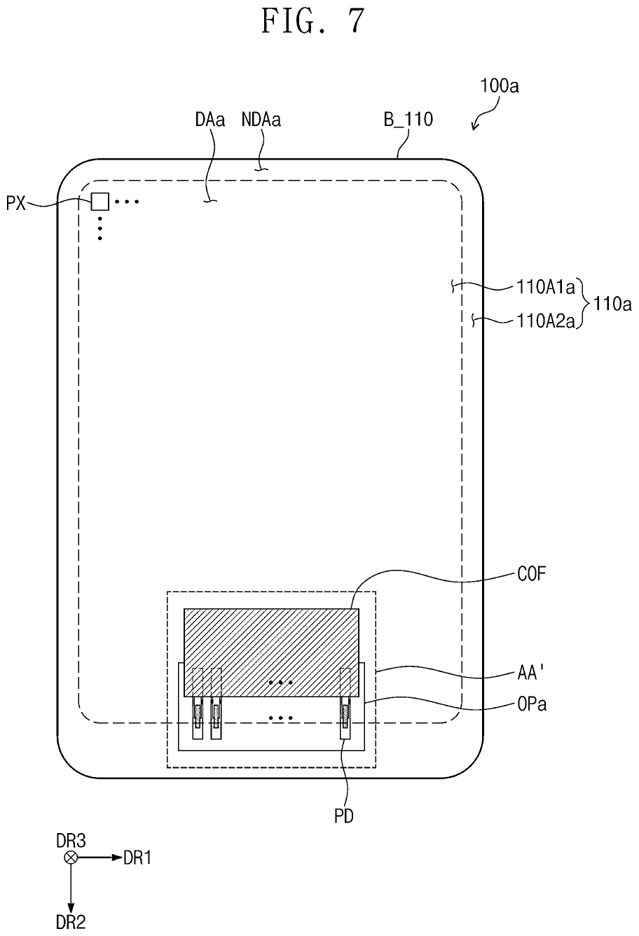

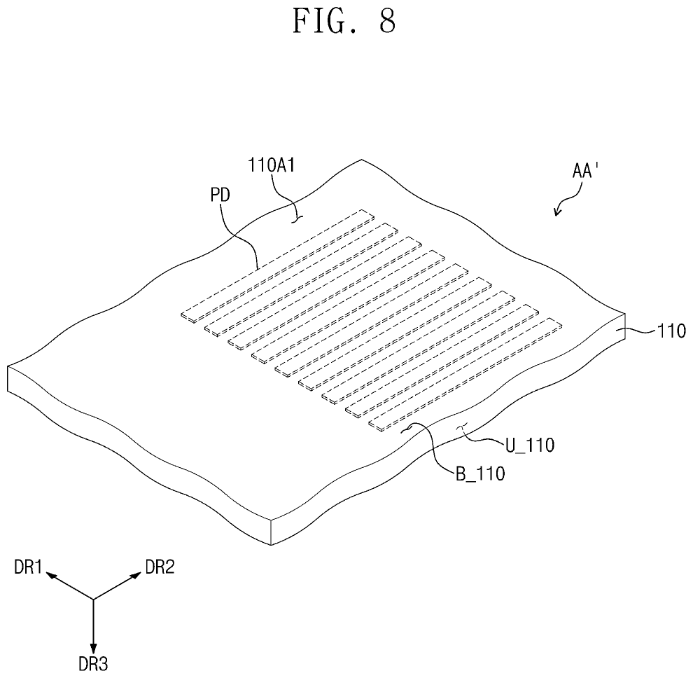

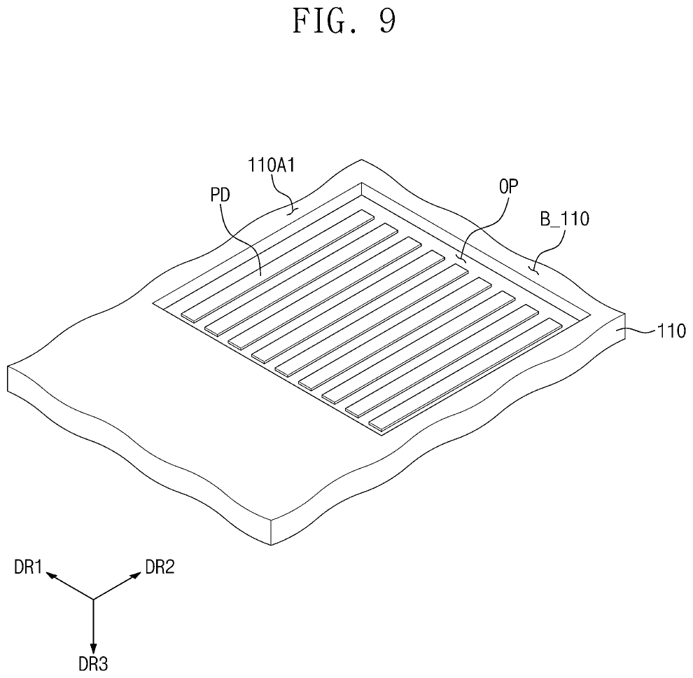

FIG. 7 is a bottom-up plan view of a display panel 100a according to another embodiment of the present disclosure.

Referring to FIG. 7, the display panel 100a may include a display region DAa and a non-display region NDAa. A first region 110A1a of a base layer 110a may overlap the display region DAa, and a second region 110A2a of the base layer 110a may overlap the non-display region NDAa in a plan view. In other words, the first region 110A1a of the base layer 110a may be a base surface provided with components disposed in the display region DAa, and the second region 110A2a of the base layer 110a may be a base surface provided with components disposed in the non-display region NDAa.

The plurality of pixels PX may be disposed in the display region DAa. In an embodiment, for example, the plurality of pixels PX may be disposed on the first region 110A1a. A plurality of lines is disposed on the base layer 110a and may be electrically connected to the pixels PX.

The plurality of pads PD may be interposed between the top surface U_110 (see FIG. 5B) and the bottom surface B_110 of the base layer 110a. The attachable region AA′ for attaching the circuit film COF may be defined on the display panel 100a. The circuit film COF may be disposed under the display panel 100a, and may be attached to the plurality of pads PD exposed by an opening OPa defined in the base layer 110a.

The attachable region AA′ for attaching the circuit film COF may be defined on the display panel 100a. The attachable region AA′ of FIG. 7 may overlap the display region DAa and the non-display region NDAa. In other words, the opening OPa of the base layer 110a may overlap the first region 110A1a and the second region 110A2a of the base layer 110a in a plan view.

FIGS. 8 to 13 are perspective views illustrating a portion of a method of manufacturing a display panel according to an embodiment of the present disclosure. In the following description made with reference to FIGS. 8 to 13, the same/similar reference numerals will be assigned to the same/similar components to components described with reference to FIGS. 1 to 7 and the redundant duplication will be omitted.

According to an embodiment of the present disclosure, a method for manufacturing a display panel includes preparing for a base layer including a first sub-base layer, barrier layers disposed on the first sub-base layer, a second sub-base layer disposed on the barrier layers, and a plurality of pads disposed in the barrier layers, forming an opening such that the plurality of pads are exposed by etching a portion of the base layer, preparing for a circuit film having a preliminary circuit film line provided in the circuit film, forming a circuit film line from the preliminary circuit film line by irradiating a laser beam to the circuit film, disposing the base layer and the circuit film such that the plurality of pads and the circuit film line overlap each other on a stage and disposing a transfer substrate on the base layer, and forming a conductive pattern on the plurality of pads and the circuit film line, where the forming of the conductive pattern includes: irradiating a first laser beam on the transfer substrate.

Hereinafter, a method of forming the conductive pattern MF will be described with reference to FIGS. 8 to 13. FIGS. 8 to 13 mainly illustrate the attachable region AA′ of the base layer 110.

Referring to FIG. 8, the method of manufacturing the display panel according to the present embodiment may include preparing for the base layer 110. The base layer 110 may include polyimide (PI). The base layer 110 may include the top surface U_110 and the bottom surface B_110. The top surface U_110 of the base layer 110 may be a surface in contact with the circuit layer 120 (see FIG. 3). The bottom surface B_110 of the base layer 110 may be a surface facing the top surface U_110 of the base layer 110 and the bottom surface of the display panel 100 (see FIG. 3).

The base layer 110 provided according to the present embodiment may include the plurality of pads PD therein. The plurality of pads PD may extend in the second direction DR2 inside the base layer 110. The base layer 110 may include the first region 110A1 and the second region 110A2 (see FIG. 4). The first region 110A1 of the base layer 110 may overlap the display region DA (see FIG. 4) of the display panel 100, and the second region 110A2 of the base layer 110 may overlap the non-display region NDA (see FIG. 4) of the display panel 100 in a plan view. In other words, the plurality of pixels PX (see FIG. 4) may be disposed on the first region 110A1 of the base layer 110. FIG. 8 illustrates the attachable region AA′ overlapping the first region 110A1 in a plan view.

Thereafter, referring to FIG. 9, the method of manufacturing the display panel according to the present embodiment may include etching a portion of the base layer 110 to form the opening OP to expose the plurality of pads PD. The opening OP may be formed by etching a portion of the base layer 110 in the thickness direction of the base layer 110 from the bottom surface B_110 of the base layer 110. In other words, the opening OP may be defined in the thickness direction (e.g., the third direction DR3) of the base layer 110.

The opening OP of the base layer 110 may overlap the first region 110A1 of the base layer 110 in a plan view. However, the position of the opening OP of the base layer 110 is provided only for the illustrative purpose, and the present disclosure is not limited thereto. For another example, the opening OP of the base layer 110 may overlap the first region 110A1 and the second region 110A2 (see FIG. 4) in a plan view.

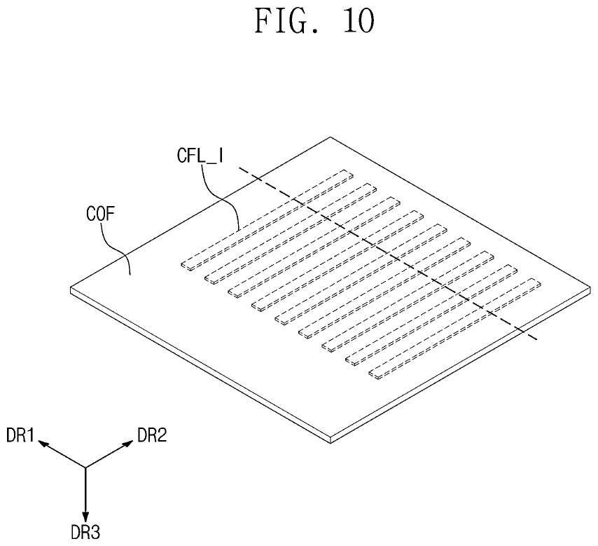

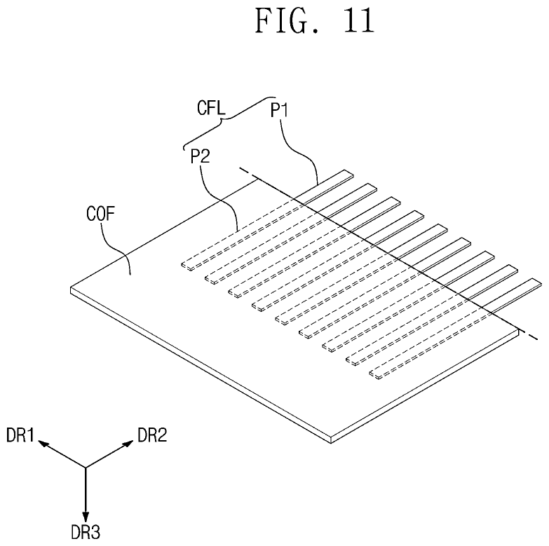

Thereafter, referring to FIG. 10, the method of manufacturing the display panel according to the present embodiment may include preparing for the circuit film COF. The circuit film COF provided in the present embodiment may include a preliminary circuit film line CFL_I therein. The preliminary circuit film line CFL_I may extend in the second direction DR2 inside the circuit film COF. The circuit film COF may include polyimide (PI), and the preliminary circuit film line CFL_I may include a metallic material. In an embodiment, for example, the preliminary circuit film line CFL_I may include copper (Cu) or silver (Ag).

Thereafter, referring to FIG. 11, the method of manufacturing the display panel according to the present embodiment may include forming the circuit film line CFL from the preliminary circuit film line CFL_I. The forming of the circuit film line CFL may include etching a portion of the circuit film COF to expose of the preliminary circuit film line CFL_I. In an embodiment, for example, a portion of the circuit film COF may be etched to expose the portion of the preliminary circuit film line CFL_I inside the circuit film COF by irradiating a laser beam to the circuit film COF. The circuit film line CFL may include a first portion P1 and a second portion P2. The first portion P1 of the circuit film line CFL may be exposed to the outside of the circuit film COF, and the second portion P2 of the circuit film line CFL may be included in the circuit film COF. In an embodiment, for example, the first portion P1 of the circuit film line CFL may extend from the circuit film COF in the second direction DR2.

According to the present disclosure, as an opening (see FIG. 9) is defined in the base layer 110 (FIG. 9), and the circuit film line CFL exposed to the outside of the circuit film COF is formed, an indentation may be reduced or removed in the process in which the circuit film line CFL is welded to the pad PD (see FIG. 9) thereafter. Accordingly, even if the circuit film COF is disposed in a region overlapping the display region DA (see FIG. 4) in a plan view, the display quality of the display device 1000 (see FIG. 1) according to the present disclosure may be improved.

FIG. 12A illustrates a step of forming the conductive pattern MF. FIGS. 12B and 12C each illustrate another embodiment of FIG. 12A illustrating forming the conductive pattern MF. In other words, FIGS. 12B and 12C may correspond to the steps described with reference to FIG. 12A.

Referring to FIGS. 12A to 12C, the method of manufacturing a display panel according to the present embodiment may include disposing the base layer 110 and the circuit film COF on a stage ST, and disposing a transfer substrate TF on the base layer 110, and forming the conductive pattern MF.

The base layer 110 and the circuit film COF may be arranged such that the plurality of pads PD overlap each other the circuit film line CFL of the base layer 110 in a plan view. In other words, the base layer 110 and the circuit film COF may be disposed in the opening OP of the base layer 110 such that the plurality of pads PD, a portion of the circuit film COF, and the circuit film line CFL overlap each other in a plan view. The transfer substrate TF disposed on the base layer 110 may include the donor film DF and a transparent substrate TS. The transparent substrate TS may be disposed on the donor film DF. The transparent substrate TS may support the donor film DF.

First, referring to FIG. 12A, the conductive pattern MF may be formed on the plurality of pads PD and the circuit film line CFL by irradiating a first laser beam LS1 to the transfer substrate TF. The forming of the conductive pattern MF may include irradiating the first laser beam LS1, changing a direction of the first laser beam LS1, and transferring a portion of the donor film DF.

A laser LSD (i.e., laser generator) may irradiate the first laser beam LS1 in a direction parallel to the first direction DR1. In an embodiment, for example, the laser LSD may irradiate the first laser beam LS1 in a direction opposite to the first direction DR1.

Thereafter, the direction of the first laser beam LS1 may be changed to the third direction DR3 by a lens LL disposed on the transfer substrate TF. The third direction DR3 may be a direction crossing the first direction DR1. For example, the third direction DR3 may be a direction toward the transparent substrate TS. In the present specification, directions indicated by the first to third directions DR1, DR2, and DR3 are relative concepts and may be converted into other directions.

Thereafter, the first laser beam LS1 irradiated toward the transparent substrate TS may pass through the transparent substrate TS, such that a portion of the donor film DF may be transferred. A portion of the transferred donor film DF may be disposed on the plurality of pads PD and the circuit film line CFL to form the conductive pattern MF. The conductive pattern MF may connect the plurality of pads PD with the circuit film line CFL.

The forming of the conductive pattern MF may further include allowing the laser LSD and the lens LL to move in the first direction DR1 or the second direction DR2. The laser LSD and the lens LL may move in the first direction DR1 or the second direction DR2 to change the position of the first laser beam LS1 irradiated to the transfer substrate TF. In an embodiment, for example, the position of the first laser beam LS1 may be moved to transfer some of the donor film DF corresponding to one pad PD and one circuit film line CFL, and the first conductive pattern MF may be formed from some of the transferred donor film DF. Thereafter, the position of the first laser beam LS1 may move in a direction parallel to the first direction DR1, and a portion of the donor film DF corresponding to the second pad PD and the second circuit film line CFL may be transcribed, and a second conductive pattern MF may be formed from a portion of the transferred donor film DF.

However, the process of changing the position of the first laser beam LS1 is not limited to the method. In an embodiment, for example, forming the conductive pattern MF may further include moving the stage ST in the first direction DR1 or the second direction DR2. As the stage ST moves in the first direction DR1 or the second direction DR2, the position of the first laser beam LS1 irradiated to the transfer substrate TF may be changed.

Referring to FIG. 12B, the conductive pattern MF may be formed on the plurality of pads PD and the circuit film line CFL by irradiating the first laser beam LS1 to the transfer substrate TF. The forming of the conductive pattern MF may include irradiating the first laser beam LS1, changing the direction of the first laser beam LS1, and transferring a portion of the donor film DF by continuously changing the direction of the first laser beam LS1.

The laser LSD may irradiate the first laser beam LS1 in a direction parallel to the first direction DR1. In an embodiment, for example, the laser LSD may irradiate the first laser beam LS1 in a direction opposite to the first direction DR1.

Thereafter, the direction of the first laser beam LS1 may be changed to the third direction DR3 by a scanner SCR disposed on the transfer substrate TF. The third direction DR3 may be a direction crossing the first direction DR1. In an embodiment, for example, the third direction DR3 may be a direction toward the transparent substrate TS.

Thereafter, the scanner SCR may continuously change the direction of the first laser beam LS1. In an embodiment, for example, the scanner SCR may move the first laser beam LS1 in the first direction DR1 or the second direction DR2. The direction of the first laser beam LS1 is moved by using the scanner SCR instead of moving the laser LSD, the lens LL (see FIG. 12A), or the stage ST (see FIG. 12A), thereby reducing the time to transferring the donor film DF.

The first laser beam LS1 may be irradiated toward the transparent substrate TS while the direction of the first laser beam LS1 is continuously changed. The first laser beam LS1 may pass through the transparent substrate TS, and a portion of the donor film DF may be transferred. A portion of the transferred donor film DF may be disposed on the plurality of pads PD and the circuit film line CFL to form the conductive pattern MF. The conductive pattern MF may connect the plurality of pads PD with the circuit film line CFL.

Referring to FIG. 12C, the conductive pattern MF may be formed on the plurality of pads PD and the circuit film line CFL by irradiating a first laser beam LS1a (or a line laser beam) to the transfer substrate TF. The forming of the conductive pattern MF may include disposing a mask MK on the transfer substrate TF, irradiating the first laser beam LS1a along the mask MK, and transferring a portion of the donor film DF by the first laser beam LS1a transmitting the mask MK.

The mask MK may be disposed on the transfer substrate TF. The mask MK may include the plurality of mask openings OP_M. Although FIG. 12C illustrates five mask openings OP_M, the present disclosure is not limited thereto. For another example, the number of mask openings OP_M may correspond to the number of conductive patterns MF to be formed.

The laser LSD may irradiate the first laser beam LS1a in a direction parallel to the third direction DR3. The third direction DR3 may be a direction toward the transparent substrate TS. In an embodiment, for example, the laser LSD may irradiate the first laser beam LS1a toward the third direction DR3 while moving in the direction parallel to the first direction DR1. The first laser beam LS1a may be a line laser.

The first laser beam LS1a transmitted through the mask MK may pass through the transparent substrate TS of the transfer substrate TF. A portion of the donor film DF may be transferred by the first laser beam LS1a transmitted through the transparent substrate TS. A portion of the transferred donor film DF may be disposed on the plurality of pads PD and the circuit film line CFL to form the conductive pattern MF. The conductive pattern MF may connect the plurality of pads PD to the circuit film line CFL. According to the present disclosure, as the donor film DF is transferred using the line laser LS1a and the mask MK, the time for forming the conductive pattern MF by transferring the donor film DF may be reduced.

The conductive pattern MF according to the present disclosure may be formed by transferring the donor film DF. In this case, the distance between the conductive patterns MF may be formed shorter, as compared with when the conductive material is ink-applied. In addition, the conductive pattern MF formed by transferring the donor film DF may be in the form of a thin film. In this case, damage to the base layer 110 due to the laser process may be reduced or removed compared with that the conductive material is applied in a hemispherical shape.

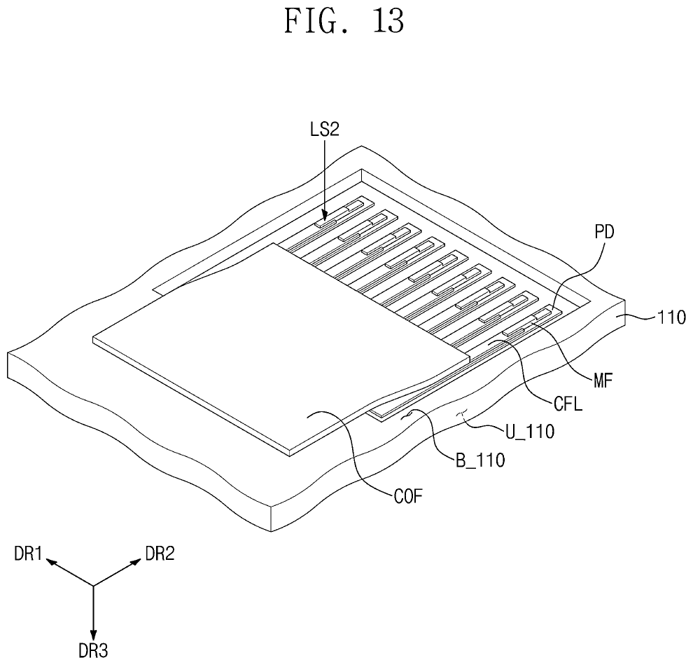

After forming the conductive pattern MF, referring to FIG. 13, the method of manufacturing the display panel according to an embodiment of the present disclosure may further include irradiating a second laser LS2 to a region where the circuit film line CFL and the conductive pattern MF overlap each other in a plan view. The second laser LS2 may be an infrared laser. The second laser LS2 may pass through the conductive pattern MF to connect the circuit film line CFL with the conductive pattern MF. In an embodiment, for example, the second laser LS2 may combine the boundaries between the circuit film line CFL and the conductive pattern MF. As the second laser LS2 is further irradiated, the connecting force between the circuit film line CFL and the conductive pattern MF may be improved, and thus the connecting force between the circuit film line CFL and the pad PD may be improved.

According to an embodiment, the area of the non-display region may be reduced. Accordingly, the display device reduced in bezel width may be provided.

According to the present disclosure, a conductive pattern may be formed by transferring a donor film. The transferring of the donor film may allow the distance between the conductive patterns to be shorter rather than coating the conductive material in the form of ink. In addition, the conductive pattern formed by transferring the donor film may be the form of a thin film. This case may more reduce or remove the damage to the base layer, which is caused through the following laser process, when compared with coating the conductive material in the form of a hemispherical form.

In addition, in a method for manufacturing a display panel according to the present disclosure, as the opening is defined in a base layer, and the circuit film line exposed to the outside of the circuit film is formed, the indentation may be reduced or removed in the process in which the circuit film line is welded to the pad thereafter. Accordingly, even though the circuit film is formed in a region overlapping the display region in a plan view, the display quality of the display device according to the present disclosure may be improved.

Although an embodiment of the present disclosure has been described for illustrative purposes, those skilled in the art will appreciate that various modifications, and substitutions are possible, without departing from the scope and spirit of the invention as disclosed in the accompanying claims. Accordingly, the technical scope of the invention is not limited to the detailed description of this specification, but should be defined by the claims.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method for manufacturing a display panel, the method comprising:
preparing for a base layer including a pad inside the base layer;
forming an opening to etch a portion of the base layer to expose the pad;
preparing for a circuit film having a preliminary circuit film line provided in the circuit film;
forming a circuit film line from the preliminary circuit film line by irradiating a laser beam to the circuit film;
disposing the base layer and the circuit film such that the pad and the circuit film line overlap each other on a stage, and disposing a transfer substrate on the base layer; and
forming a conductive pattern on the pad and the circuit film line,
wherein the forming of the conductive pattern includes irradiating a first laser beam on the transfer substrate.

2. The method of claim 1, wherein the forming of the circuit film line includes:
etching a portion of the circuit film to expose a portion of the preliminary circuit film line.

3. The method of claim 1, wherein the transfer substrate includes a donor film and a transparent substrate disposed on the donor film.

4. The method of claim 3, wherein the forming of the conductive pattern includes:
irradiating, by a laser generator, the first laser beam in a first direction;
changing a direction of the first laser beam from the first direction toward the transparent substrate through a lens disposed on the transfer substrate; and
transferring a portion of the donor film through the first laser beam irradiated toward the transparent substrate.

5. The method of claim 4, wherein the forming of the conductive pattern further includes:
moving the laser generator and the lens in the first direction or a second direction crossing the first direction.

6. The method of claim 4, wherein the forming of the conductive pattern further includes:
moving the stage in the first direction or a second direction crossing the first direction.

7. The method of claim 3, wherein the forming of the conductive pattern includes:
irradiating, by a laser generator, the first laser beam in a first direction;
changing a direction of the first laser beam from the first direction toward the transparent substrate through a scanner disposed on the transfer substrate; and
transferring, by the scanner, a portion of the donor film by continuously changing the direction of the first laser beam.

8. The method of claim 3, wherein the forming of the conductive pattern includes:
disposing a mask on the transfer substrate;
irradiating, by a laser generator, the first laser beam along the mask; and
transferring a portion of the donor film by the first laser beam transmitted through the mask, and
wherein the first laser beam is a line laser beam.

9. The method of claim 3, further comprising:
irradiating a second laser beam to an overlap region between the circuit film line and the conductive pattern,
wherein the second laser beam connects the circuit film line to the conductive pattern through the conductive pattern.

10. The method of claim 9, wherein the second laser beam is an infrared laser beam.

11. The method of claim 1, wherein the base layer includes:
a first region and a second region, and
wherein a plurality of pixels is disposed on the first region, and the opening overlaps the first region of the base layer.

12. The method of claim 1, wherein the disposing of the base layer and the circuit film, and disposing of the transfer substrate on the base layer includes:
disposing the base layer and the circuit film such that the pad and the circuit film line overlap each other in the opening of the base layer.

13. The method of claim 1, wherein the disposing of the base layer and the circuit film, and disposing of the transfer substrate on the base layer includes:
disposing the base layer and the circuit film such that the pad, a portion of the circuit film, and the circuit film line overlap each other in the opening of the base layer.

14. A display panel comprising:
a base layer in which a first region and a second region are defined;
a plurality of pixels disposed on the first region of the base layer;
a pad interposed between a top surface and a bottom surface of the base layer;
a circuit film disposed on the pad and the bottom surface of the base layer;
a circuit film line disposed on the pad, and having a portion extending from the circuit film; and
a conductive pattern disposed on the circuit film line and the pad,
wherein the base layer has an opening defined therein in a thickness direction of the base layer, and the pad, the circuit film line, and the conductive pattern are disposed in the opening.

15. The display panel of claim 14, wherein a portion of the circuit film is disposed inside the opening.

16. The display panel of claim 14, wherein the base layer includes:
a first sub-base layer including the bottom surface of the base layer and having the opening defined in the first sub-base layer;
barrier layers disposed on the first sub-base layer; and
a second sub-base layer disposed on the barrier layers and including the top surface of the base layer, and
wherein the pads is disposed in the barrier layers, and is exposed by the opening of the first sub-base layer.

17. The display panel of claim 14, wherein a width of the circuit film line is equal to or less than a width of the pad in a plan view.

18. The display panel of claim 14, wherein a width of the conductive pattern may be equal to or less than a width of the circuit film line in a plan view.

19. The display panel of claim 14, wherein the opening overlaps the first region.

20. The display panel of claim 14, wherein the opening overlaps the first region and the second region.

21. The display panel of claim 14, wherein the conductive pattern connects the circuit film line to the pad.

22. The display panel of claim 14, wherein the conductive pattern has a form of a thin film.
